(19) United States
(12) Patent Application Publication
(10) Pub. No.: US 2006/0183265 A1
(43) Pub. Date: Aug. 17, 2006

(54) Image sensor having improved sensitivity and method for making same

(75) Inventors: Tae Seok Oh, Seoul (KR); Duk Min Yi, Yongin-Si (KR); June Taeg Lee, Suwon-Si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/244,189

(22) Filed: Oct. 5, 2005

(30) Foreign Application Priority Data
Feb. 14, 2005 (KR) 10-2005-0011838

(51) Int. Cl. H01L 21/00

(52) U.S. Cl. 438/65; 438/70

(57) ABSTRACT

An image sensor having improved sensitivity and method for making same include a substrate having an active pixel region with a peripheral circuit region surrounding the active pixel region; a plurality of photo conversion elements disposed in the active pixel region, each photodiode is configured for receiving light through a lens and an opening formed between a plurality of layers of interlayer dielectrics formed on top of each other above the substrate; and a plurality of interconnections electrically connecting to the photo conversion elements disposed within the active pixel region, wherein the distance between the lens and the photo conversion elements is shorter than the distance between the substrate and the top interlayer dielectric in the peripheral circuit region.

### BACKGROUND OF THE INVENTION

1. Technical Field

The present invention relates to a structure of an image sensor device and a method for fabricating the same. More particularly, the present invention relates to an image sensor device having a copper interconnection and improved sensitivity and a method for fabricating the same.

2. Discussion of the Related Art

Semiconductor image sensing devices are widely used for capturing images in a variety of applications such as digital cameras, camcorders, printers, scanners, etc. The semiconductor image sensing devices include image sensors that capture optical information and convert the optical information into electrical signals, which are then processed, stored, and otherwise manipulated to result in projection of the captured images onto a display or print medium. There are two types of image sensor devices which are widely used: a charge coupled device (CCD) type and CMOS image sensors (CISs) type. CCD sensors operate with low noise and device uniformity, but generally require higher power consumption and lower speed operation than the CIS type. The lower power consumption and higher speed capability are important factors when the image sensors are used in portable electronic devices such as in a handheld phone with an integrated camera. In such applications, CISs are the preferred image sensors over CCDs.

As electronic devices such as PDAs and handheld phones become more portable and more and more features are incorporated in the electronic devices, there is increased pressure to make the image sensor devices smaller but the number of interconnects higher.

Aluminum has traditionally been used in the integrated circuit (IC) industry as a metal for making electrical interconnections in IC devices; however, it is generally difficult to form aluminum interconnections for a semiconductor device having a design rule or pattern thickness below 0.13 μm. Copper is an alternative to aluminum in applications where the design rule or pattern thickness is below 0.13 μm. Copper is an attractive material for use as an interconnection contact because its resistivity, which is around 1.7 μΩcm, is lower than that of aluminum alloy, which is around 3.2 μΩcm, and tungsten, which is greater than 15 μΩcm. Also, copper is more reliable than aluminum alloy. Further, the RC delay of a copper interconnection is shorter than that obtained with other metals, such as aluminum alloy. The better conductivity and the shorter delay reduce cross talk among the electrically conductive elements. In short, the use of copper as an interconnection contact results in overall improved device performance. However, copper atoms tend to diffuse into surrounding materials, such as into an interlayer dielectric layer, and can negatively impact the electrical characteristics of underlying transistors or other elements.

U.S. Pat. No. 6,861,686 to Lee et al. discloses use of copper interconnections in a CIS type image sensor device. Lee discloses use of diffusion barrier layers to prevent diffusion of the copper into surrounding materials. The disclosure of U.S. Pat. No. 6,861,686 is incorporated by reference herein.

FIG. 1A shows a conventional CIS structure with copper interconnections. As shown in FIG. 1A, photo conversion elements 52 are used to capture optical signals through corresponding optical passages 88, color filters 92 and lens 96. Interconnections and contacts such as 58, 59, 64, 78, and 80 are made of copper. Etch stop layers 56, 60, 62, 67, 69, 74, and 76 are used to prevent copper diffusion. Typically, etch stop layers are formed of SiN or SiC. However, these materials are opaque, and would block the passage of the optical signals unless they are removed from the optical passages 88. Interlayer dielectric layers such as 61, 68, and 77 are interposed between the diffusion barrier layers. The interlayer dielectric layers also act to deflect or reflect the optical signals and they are also removed from the optical passages. Gap filling material is used to fill the openings of the optical passages. Although the gap filling material must, of course, be optically transparent, a significantly thick amount of the gap filing material would nevertheless impede and reduce the level of optical signals from reaching the photo conversion elements 52.

### SUMMARY OF THE INVENTION

An embodiment of the present invention provides a method of forming an image sensor device, comprising providing a substrate having an active pixel region and a peripheral circuit region; disposing a plurality of photo conversion elements in the active pixel region; forming a plurality of transistors in the active pixel region; forming on top of the substrate a plurality of layers of interlayer dielectrics having an etch stop layer between each adjacent layer of interlayer dielectric; forming interconnections within the interlayer dielectrics connecting to respective photo conversion elements; providing a recess in the active pixel region by etching a plurality of layers of interlayer dielectrics; providing openings through remaining plurality of layers of interlayer dielectrics to form an optical path for the photo conversion elements; filling the openings with transparent material; and forming color filters and lens above the openings, wherein the distance of the optical path from the photodiode to the lens is shorter than the distance from the substrate to the top layer of interlayer dielectric in the peripheral circuit region.

Another embodiment of the present invention provides a method of forming an image sensor device, comprising forming an active pixel region with a plurality of photo conversion elements disposed in a substrate; forming a plurality of transistors connecting to respective photo conversion elements in the active pixel region; forming a first interlayer dielectric on the substrate; forming first metal contacts through the first interlayer dielectric; forming a first etch stop layer on the first interlayer dielectric; forming a second interlayer dielectric on the etch stop layer; forming first interconnections through the second interlayer dielectric and connecting to the metal contacts; forming a second etch stop layer on the second interlayer dielectric; forming a third interlayer dielectric, a third etch stop, and a fourth interlayer dielectric on the second etch stop layer; forming second interconnections through the third interlayer dielectric, forming a fourth etch stop layer; depositing a fifth interlayer dielectric, a fifth etch stop and a sixth interlayer dielectric sequentially on the fourth etch stop layer; forming third and fourth interconnections; forming a passivation layer; forming a first photoresist pattern which opens the active pixel region; partial etching to form a preliminary recess region; sequentially etching passivation layer, eighth interlayer dielectric, seventh etch stop layer, seventh interlayer dielectric, sixth etch stop layer, sixth interlayer dielectric, fifth etch stop layer, and at least partially the fifth interlayer dielectric; etching the remaining fifth interlayer dielectric to form a recessed region which reveals a fourth etch stop layer; removing the first photoresist pattern; forming second photoresist patterns with openings corresponding to respective photo conversion elements; forming second openings by etching the interlayer dielectric structure of active pixel region; removing the second photoresist pattern; depositing a transparent filling material; forming color filters; forming a flattening layer on the color filters; and forming a plurality of lenses on the flattening layer.

According to an alternative embodiment of the invention, the fifth interlayer dielectric may be about 1.5 to about 3 times thicker than its adjacent layers of interlayer dielectrics. The interlayer dielectrics may be made of transparent material. The filling material may have a higher refractive index than the interlayer dielectrics, and may be made from a resin or flowable oxide, and may contact the photo conversion elements. The first flattening layer may be about 0.2 μm to about 0.6 μm in thickness. The interlayer dielectrics may have substantially the same thickness except for the first interlayer dielectric. The interconnections may be made of copper. The substrate may be made of silicon or SOI. The method may further include another flattening layer between the filling material and the color filters.

Another embodiment of the present invention provides an image sensor device, comprising: a substrate having an active pixel region with a peripheral circuit region surrounding the active pixel region; a plurality of photo conversion elements disposed in the active pixel region, each photodiode is configured for receiving light through a lens and an opening formed between a plurality of layers of interlayer dielectrics formed on top of each other above the substrate; and a plurality of interconnections electrically connecting to the photo conversion elements disposed within the active pixel region, wherein the distance between the lens and the photo conversion elements is shorter than the distance between the substrate and the top interlayer dielectric in the peripheral circuit region.

In the image sensor device, the interconnections may be made of copper. The device may further include color filters disposed between the lens and the photo conversion elements.

Yet another embodiment of the present invention provides a method of forming an image sensor device, comprising forming an active pixel region with a plurality of photo conversion elements disposed in a substrate; forming a plurality of transistors connecting to respective photo conversion elements in the active pixel region; forming a first interlayer dielectric on the substrate; forming first metal contacts through the first interlayer dielectric; forming a first etch stop layer on the first interlayer dielectric; forming a second interlayer dielectric on the etch stop layer; forming first interconnections through the second interlayer dielectric and connecting to the metal contacts; forming a second etch stop layer on the second interlayer dielectric; forming a third interlayer dielectric, a third etch stop, and a fourth interlayer dielectric on the second etch stop layer; forming second interconnections through the third interlayer dielectric, the first and second interconnections being formed using copper and surrounding barrier layer; forming a fourth etch stop layer; depositing a fifth interlayer dielectric, a fifth etch stop and a sixth interlayer dielectric sequentially on the fourth etch stop layer; forming third and fourth interconnections using copper and surrounding barrier layer; forming a passivation layer; forming a first photoresist pattern which opens the active pixel region; partial etching to form a preliminary recess region; sequentially etching passivation layer, eighth interlayer dielectric, seventh etch stop layer, seventh interlayer dielectric, sixth etch stop layer, sixth interlayer dielectric, fifth etch stop layer, and at least partially the fifth interlayer dielectric; etching the remaining fifth interlayer dielectric to form a recessed region which reveals a fourth etch stop layer; removing the first photoresist pattern; forming second photoresist patterns with openings corresponding to respective photo conversion elements; forming second openings by etching the interlayer dielectric structure of active pixel region; removing the second photoresist pattern; depositing a transparent filling material; forming color filters; forming a flattening layer on the color filters; and forming a plurality of lenses on the flattening layer.

### BRIEF DESCRIPTION OF THE DRAWINGS

The present invention will become more apparent to those of ordinary skill in the art by describing in detail preferred embodiments thereof with reference to the attached drawings in which:

FIG. 1A shows a cross-sectional view of a conventional image sensor device.

FIG. 1B illustrates a cross-sectional view of an image sensor device according to an embodiment of the present invention;

FIGS. 2A-2J illustrate cross-sectional views of the image sensor device illustrated in FIG. 1B at various stages of formation;

FIG. 3 illustrates a cross-sectional view of an image sensor device according to another embodiment of the present invention;

FIGS. 4A-4C illustrate cross-sectional views of the image sensor device illustrated in FIG. 3 at various stages of formation;

FIG. 5 illustrates a cross-sectional view of an image sensor device according to another embodiment of the present invention;

FIG. 6 illustrates a cross-sectional view of the image sensor device illustrated in FIG. 5 at a stage of formation;

FIG. 7 illustrates a cross-sectional view of an image sensor device according to another embodiment of the present invention;

FIGS. 8A-8B illustrate cross-sectional views of the image sensor device illustrated in FIG. 7 at various stages of formation;

FIG. 9 illustrates a cross-sectional view of an image sensor device according to another embodiment of the present invention; and

FIG. 10 illustrates a cross-sectional view of the image sensor device illustrated in FIG. 9 at a stage of formation.

### DETAILED DESCRIPTION OF PREFERRED EMBODIMENTS

The present invention will now be described more fully hereinafter with reference to the accompanying drawings, in which preferred embodiments of the invention are shown. In the drawings, the thickness of layers and regions are exaggerated for clarity. Like numbers refer to like elements throughout.

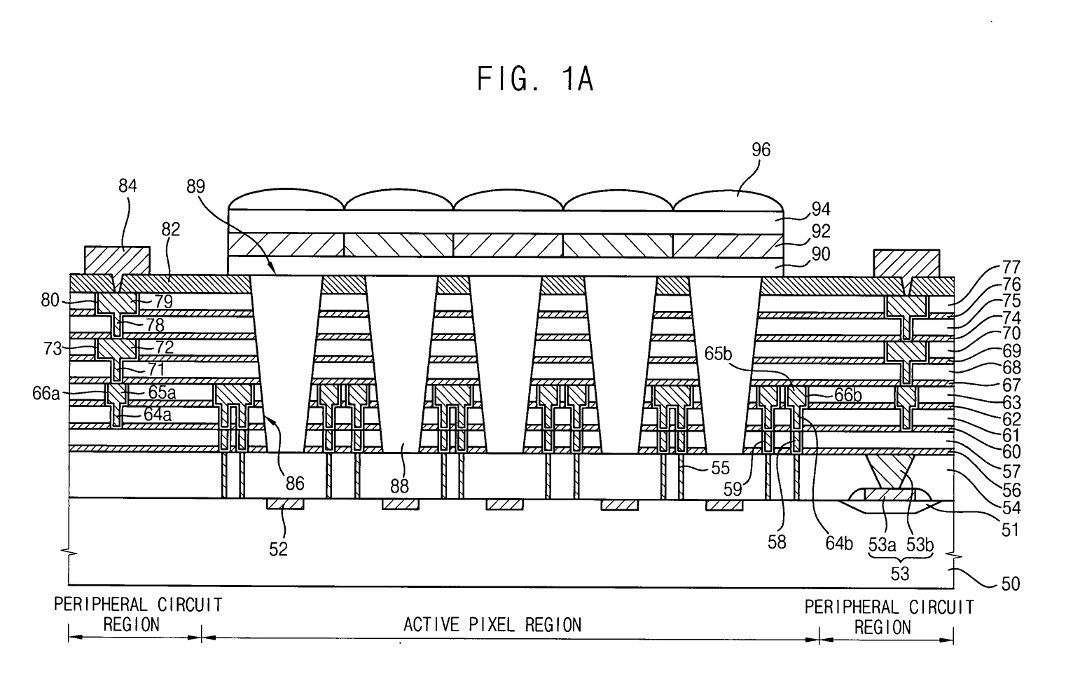

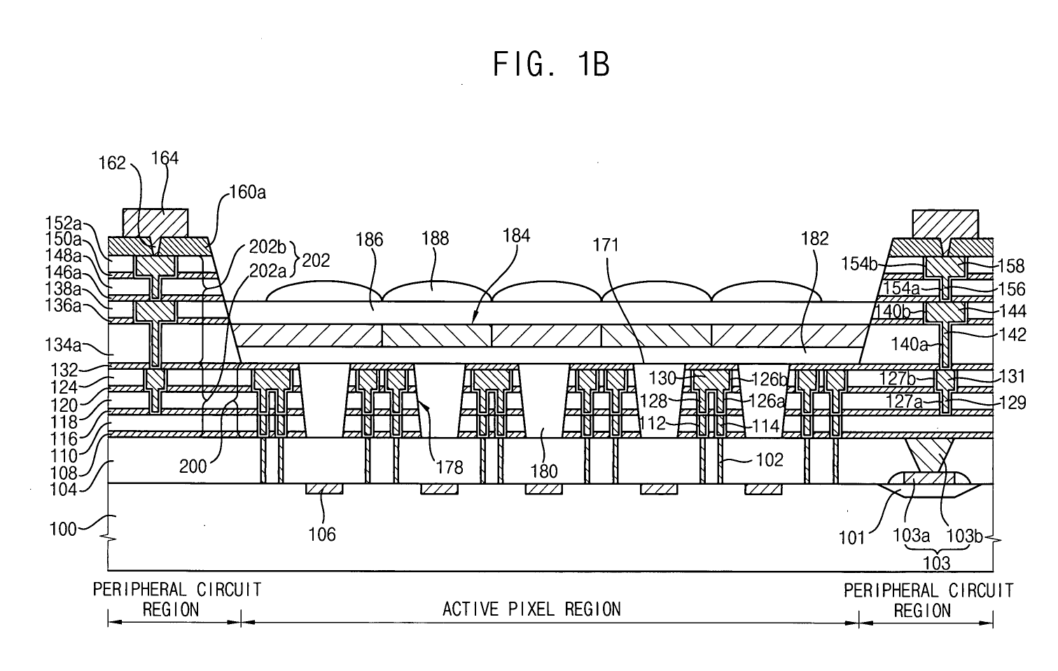

In an embodiment of the present invention, an image sensor device is provided as illustrated in FIG. 1 B. The image sensor device is preferably of the CIS type, divided into an active pixel region and peripheral circuit regions over a common substrate 100. Photo conversion elements and associated interconnections, color filters, and lens assembly are disposed in the active pixel region. Peripheral interconnections, contacts, isolation region, and circuit pads are formed in the peripheral circuit region.

The photo conversion elements 106 are formed in the active pixel region of the substrate 101. A first interlayer dielectric 104 is formed above the substrate 100. First contacts 102 are formed adjacent to the photo conversion elements 106 in the first interlayer dielectric 104. An interlayer dielectric structure 200 of the active pixel region, comprising first, second, third and fourth etch stop layers (or diffusion barrier layers) 108, 116, 120 and 132, respectively, are formed between adjacent interlayer dielectric layers. 110, 118, and 124.

Interconnections 114, 128 and 130, disposed in the interlayer dielectric structure of the active pixel region 200, connect to respective first contacts 102. Interconnection 130 may be a one or two piece structure. The contacts and interconnections are preferably copper. Thus, barrier metal layers 112, 126a and 126b are formed around respective interconnections 114, 128, and 130 to prevent diffusion of copper atoms into interlayer dielectric layers 110, 118 and 124. The image sensor device further includes a micro lens assembly 188 formed over a second flattening layer 186, which in turn is formed over a color filter 184. The color filter 184 is formed over a first flattening layer 182. Openings 180 are aligned with respective photo conversion elements 106 and microlens 188. According to the present embodiment of the present invention, it is preferred that there is a distance between the bottom of the opening to the photo conversion elements 106. The photo conversion elements 106 are devices capable of receiving optical signals or energy and converting the optical signals to electrical signals. Photodiodes and photogates may be used as photo conversion elements 106.

An interlayer dielectric structure 202 of the peripheral circuit region comprises a first portion 202a and a second portion 202b. The first portion 202a includes second contacts 129 and second interconnections 131 formed respectively within barrier metal layers 127a and 127b to prevent diffusion of copper atoms into the third interlayer dielectric layer 118 and the fourth interlayer dielectric layer 124. The second portion 202b includes third contacts 142 and third interconnections 144, and fourth contacts 156 and fourth interconnections 158. These structures are formed respectively within barrier metal layers 140a, 140b, 154a and 154b to prevent diffusion of copper atoms into the fifth, sixth, seventh and eighth interlayer dielectric layers 134a, 138a, 148a and 152a, respectively. The contacts 128, 129, 142 and 156 may be vias and the interconnections 130, 131, 144 and 158 may be trenches. The fifth, sixth and seventh etch stop layers 136a, 146a, and 150a are formed between adjacent interlayer dielectric layers.

PAD 164 is formed above the passivation layer 160a, which is formed above the eighth interlayer dielectric layer 152a. Contact hole 162 is formed between the passivation layer 160a, below PAD 164. An under interconnection 103, comprising an under interconnection pattern 103a and under interconnection plug 103b, is also formed in the peripheral circuit region. It should be noted that the present invention provides methods by which copper interconnections may be used in an image sensor device, thereby allowing fabrication of an image sensor device having a design rule or pattern thickness of less than about 0.13 μm. The etch stop layers are preferably made using Silicon nitride (SiN) or Silicon carbide (SiC). It should also be noted that the distance between the lens assembly 188 and the photo conversion elements 106 is shorter than the distance between the top of the substrate 100 to the top interlayer dielectric layer 152a. The reduced thickness in the optical passage path yields higher light sensitivity.

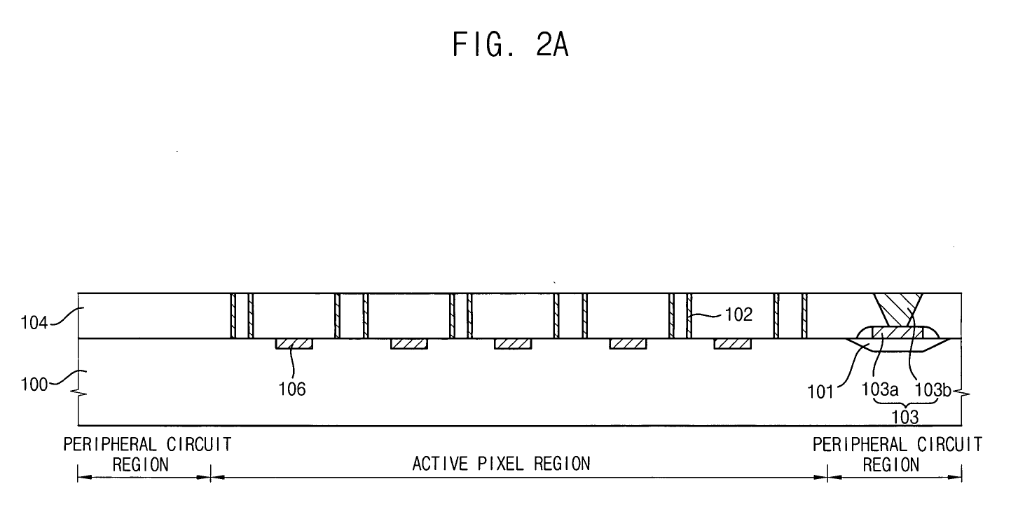

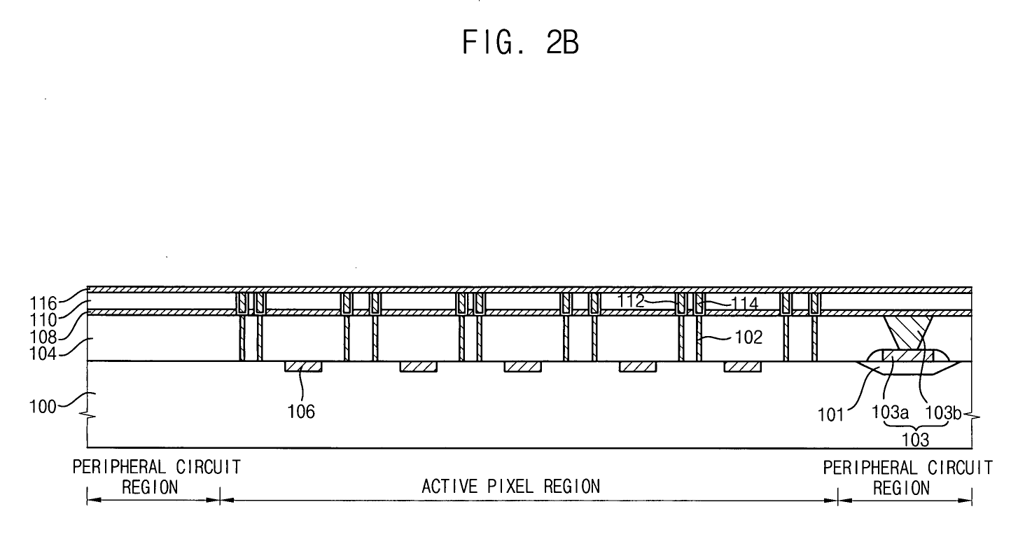

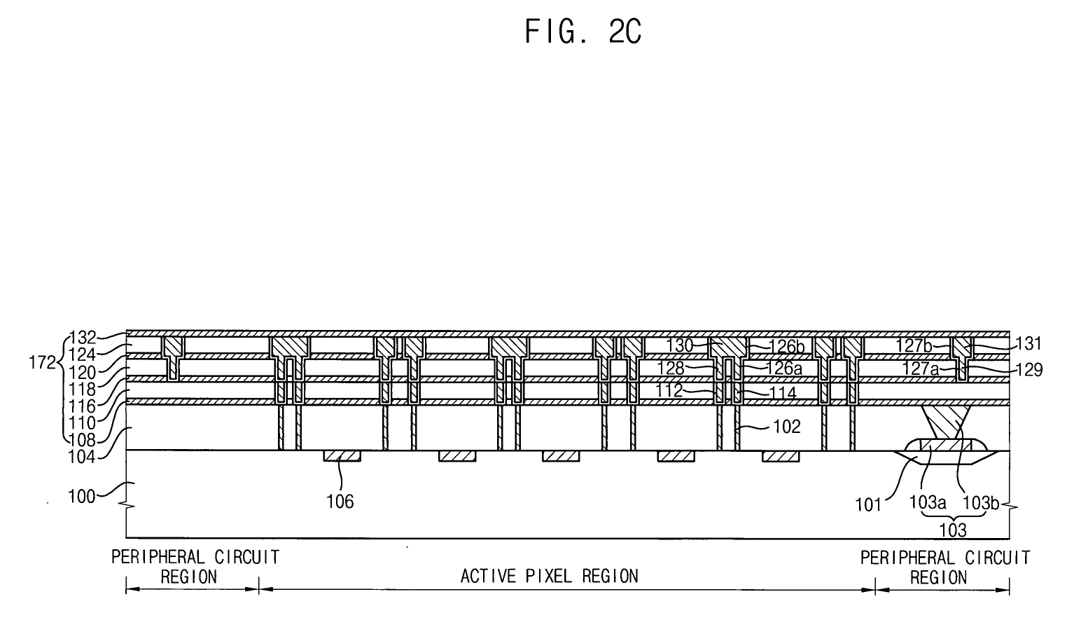

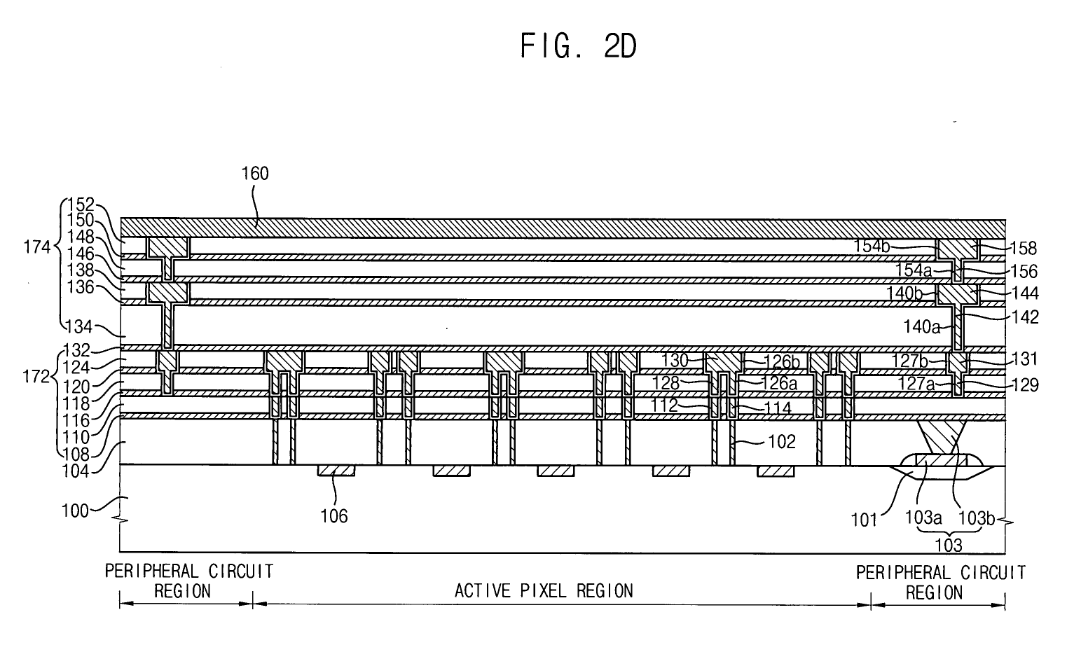

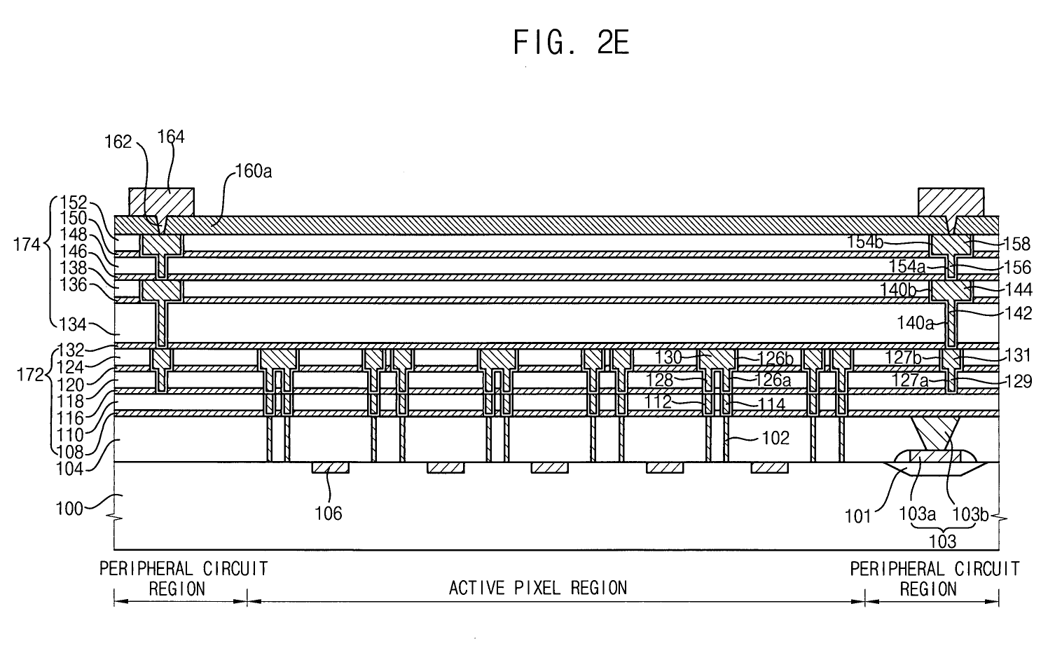

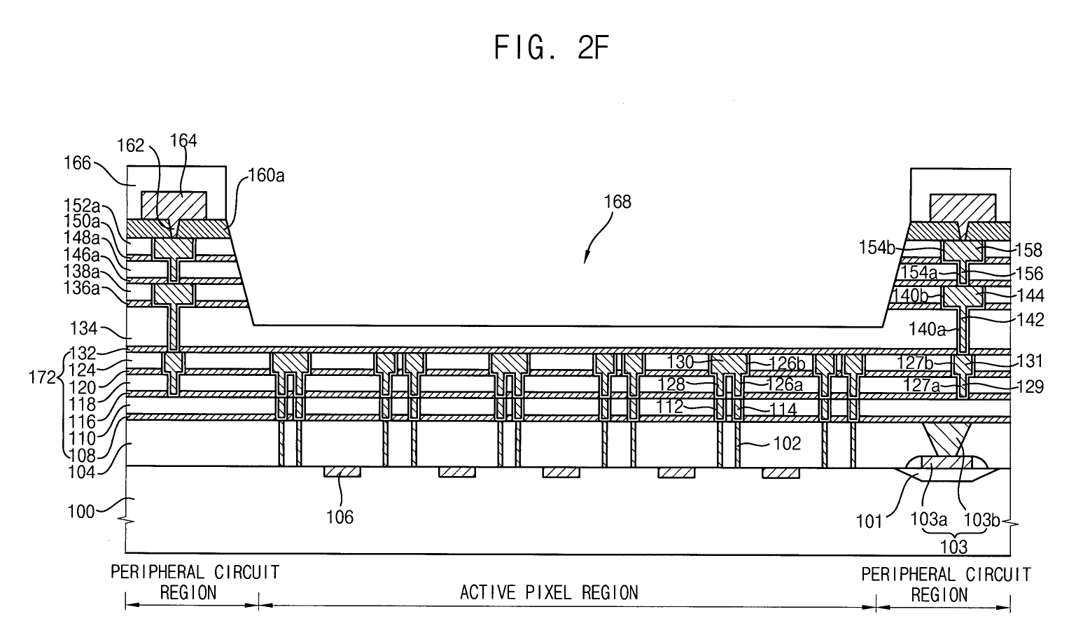

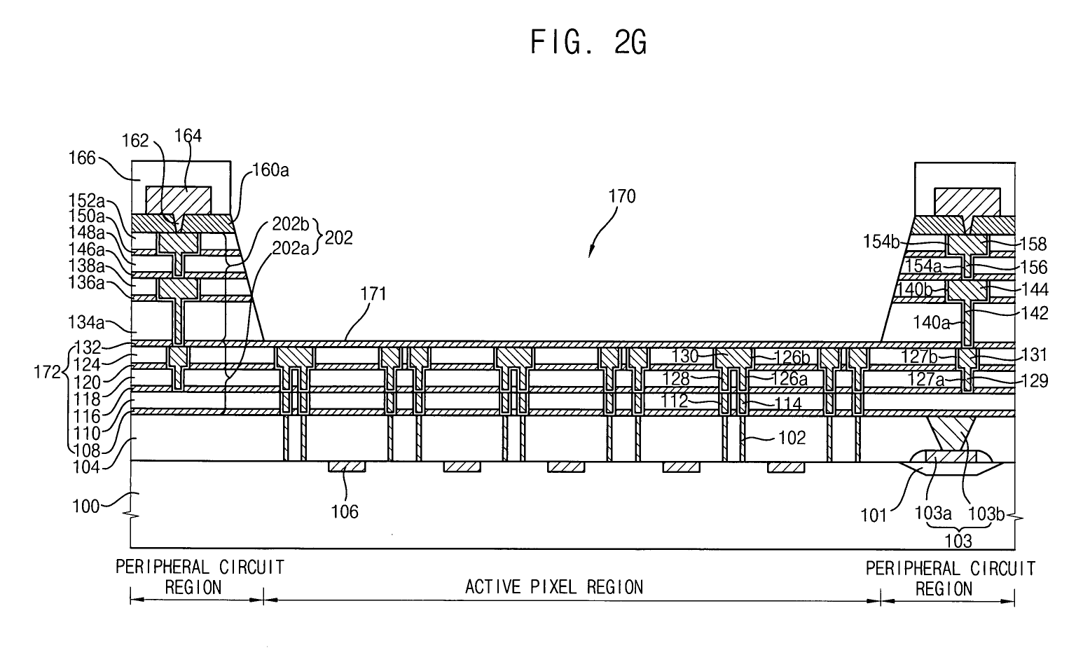

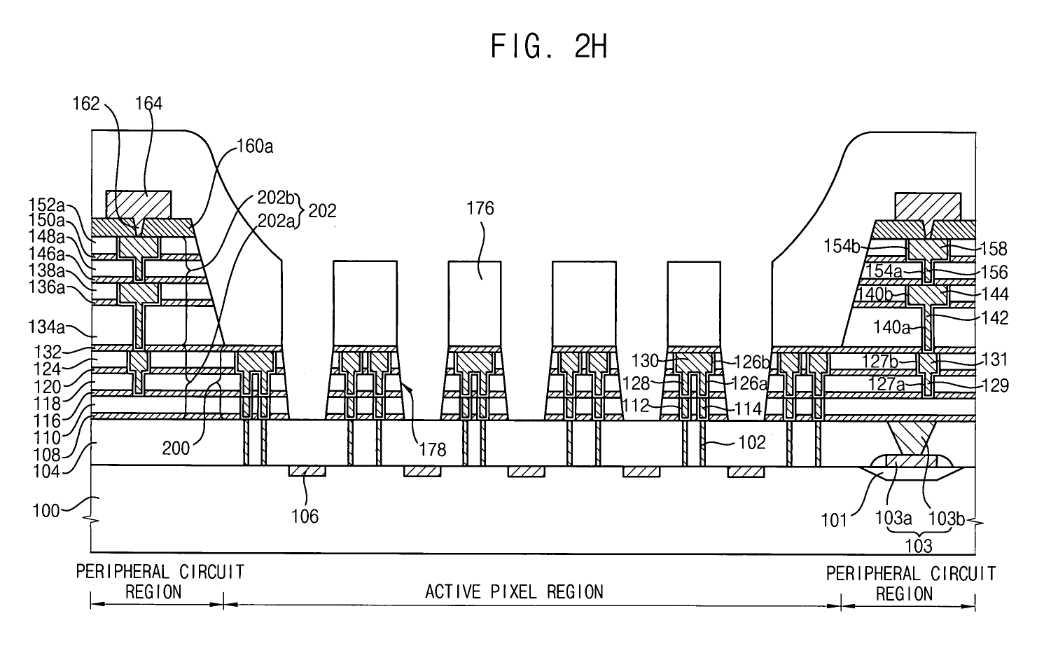

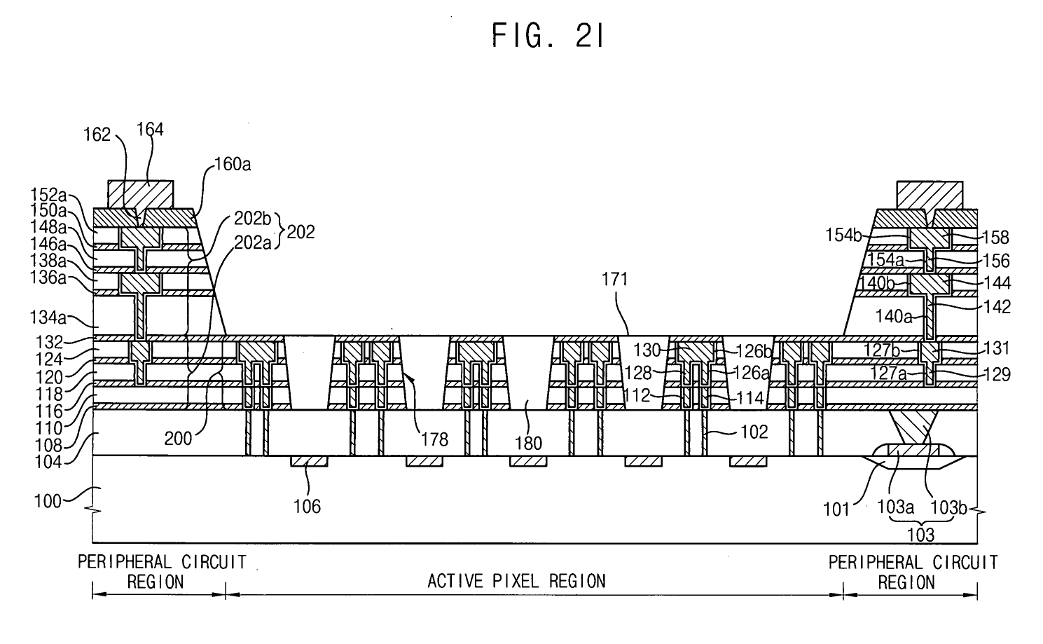

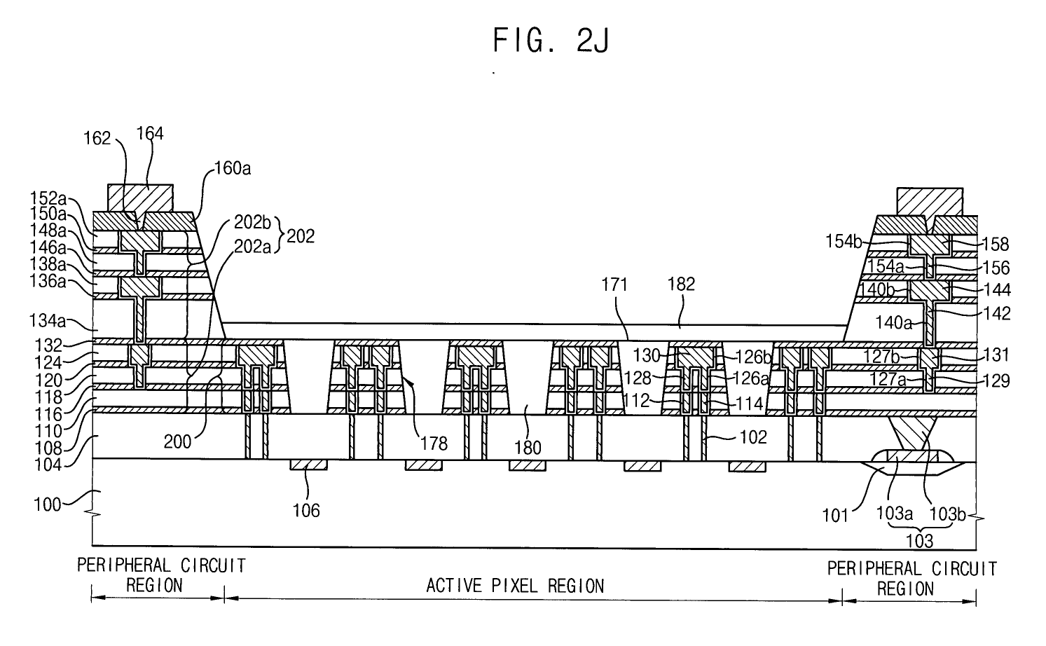

FIGS. 2A to 2J illustrate a method of forming the device according to FIG. 1B.

With reference to FIG. 2A, a shallow trench isolation region 101 is formed in the semiconductor substrate 100. A plurality of photo conversion elements 106 are formed in the active pixel region of the substrate 100. A plurality of transistors (not shown) is formed in the active pixel region and the peripheral circuit region. A first interlayer dielectric layer 104 is formed over the substrate 100. The first interlayer dielectric layer 104 may be a transparent material, such as silicon oxide (SiO₂). The first interlayer dielectric layer 104 is patterned using known techniques, such as depositing and developing a photoresist material to make a mask pattern, through which dielectric material may be removed. A pattern of the dielectric material is removed by an etch process such as plasma etching or reactive ion etching. A first contact 102 is formed in the first interlayer dielectric layer 104 by etching and depositing a metal material. The metal material may be titanium, tungsten or copper. The metal material may be deposited by electroplating, electroless plating, chemical vapor deposition, physical vapor deposition or any combination thereof. When using copper, it is preferable to use a barrier metal layer. Under construction 103, including under interconnection pattern 103a and under interconnection plug 103b, is formed in the peripheral circuit region of the first interlayer dielectric layer 104.

As illustrated in FIG. 2B, a first etch stop layer 108 is formed over the length of the first interlayer dielectric layer 104. The etch stop layer acts as a diffusion barrier layer to prevent copper from diffusing into the first interlayer dielectric layer 104. The first etch stop layer 108 may be silicon nitride (SiN) or silicon carbide (SiC), but SiC may further include N or O, and SiN may further include O. The thickness of the first etch stop layer 108 may be about 200 to about 1000 Å, and preferably about 300 to about 700 Å. Then, a second interlayer dielectric 110 is formed over the length of the first interlayer dielectric layer 104. The second interlayer dielectric layer may be made of a low k dielectric material such as SiO₂ or fluorinated silicated glass (FSG). A plurality of first interconnection 114 is formed on the active pixel region of the second interlayer dielectric 110. The first interconnection 114 may be copper and formed using known damascene techniques. A first barrier layer 112 is formed surrounding the first interconnection 114 to prevent copper diffusion. The materials used to form the first barrier layer 112 may include tantalum, tantalum nitride or a combination thereof and may be formed by using a standard sputtering method. A second etch stop layer 116 is formed over the second interlayer dielectric layer 110. The second etch stop layer may be made of SiN or SiC.

FIG. 2C shows that a third interlayer dielectric layer 118 is formed over the second etch stop layer 116, a third etch stop layer 120 is formed over the third interlayer dielectric layer 118, and a fourth interlayer dielectric layer 124 is formed over the third etch stop layer 120. A second contact 128 in the active pixel region and a second contact 129 in the peripheral circuit region are formed in the third interlayer dielectric layer 118, with a second barrier layer 126a in the active pixel region and a second barrier layer 127a in the peripheral circuit region formed around respective outer surfaces of the contacts. Similarly, a second interconnection 130 in the active pixel region and a second interconnection 131 in the peripheral circuit region, with their corresponding second barrier layer 126b and 127b around their respective outer surfaces and formed in the fourth interlayer dielectric layer 124. The contacts 128 and 129 are vias and interconnections 130 and 131 are trenches that are connected respectively. The interconnections 128, 129, 130 and 131 may be made of copper.

Formation of the contacts and interconnections is accomplished by first forming dummy holes and trenches (not shown) which are then etched in the respective interlayer dielectric layer and etch stop layers, using known damascene techniques. The copper layers in this process may be formed by first depositing a copper seed layer by sputtering, and then electroplating. Other methods, such as electroless plating, chemical vapor deposition, physical vapor deposition or a combination thereof may be used to form the copper layer. The second barrier layers 126a, 126b, 127a and 127b may be made of tantalum, tantalum nitride or a combination thereof and are used to prevent copper diffusion. A fourth etch stop layer 132 is formed on top of the fourth interlayer dielectric layer 124.

Referring to FIG. 2D, a fifth interlayer dielectric layer 134, a fifth etch stop layer 136 and a sixth interlayer dielectric layer 138 are sequentially deposited on the fourth etch stop layer 132. Third contact 142 is formed on the peripheral circuit region of the fifth interlayer dielectric layer 134, while interconnect 144 is formed on the sixth interlayer dielectric layer and located above and connected to the third contact 142. Fourth contact 156 is formed on the peripheral circuit region of the seventh interlayer dielectric layer 148, while interconnection 158 is formed on the eighth interlayer dielectric layer to be located above and connected to the third contact 148. The contacts 142 and 156 are vias, and interconnections 144 and 158 are trenches connected respectively. Third barrier layers 140a and 140b cover the third contact 142 and the third interconnection 144 respectively. Fourth barrier layers 154a and 154b cover the fourth contact 156 and the fourth interconnection 158 respectively. A passivation layer 160 is formed above the eighth interlayer dielectric layer 152. In the embodiment of FIG. 1B, the fifth interlayer dielectric layer 134 is about 1.5 times to about 3 times thicker than the other interlayer dielectrics.

As illustrated in FIG. 2E, a contact hole 162 is formed for connecting PAD 164 and the fourth interconnection 158. One method of forming the PAD 164 is through a lithography process. A metal such as aluminum for the PAD is preferred.

As illustrated in FIG. 2F, a first photoresist pattern 166 is formed above and around the PAD 164 to facilitate opening the active pixel region. Partial etching is then performed to form a preliminary access region 168 in the active pixel region. The partial etching is performed by sequentially etching passivation layer 160, the eighth interlayer dielectric layer 152, the seventh etch stop layer 150, the seventh interlayer dielectric layer 148, the sixth etch stop layer 146, the sixth interlayer dielectric layer 136 and partially the fifth interlayer dielectric layer 134. Preferably, a sloping wall is formed in the preliminary access region 168 from the etching of the 160a, 152a, 150a, 148a, 146a, 138a, 136a and 134 layers. The sloping wall facilitates easier access for subsequent processing steps.

As illustrated in FIG. 2G, the remaining fifth interlayer dielectric layer 134 is etched to form a recessed region 170, preferably with sloping walls. The recessed region 170 provides an opening in the active pixel region to reveal the fourth etch stop layer 132. The fourth etch stop layer 132 has a high selective etching condition of from about 1:10 to about 1:15. If the fifth interlayer dielectric layer 134 is a FSG and the fourth etch stop layer 132 is SiN, then the etch gases of C₄F₈, Ar and O₂, or a combination thereof, may better control the etch selectivity. Then the first photoresist pattern 166 is removed.

As illustrated in FIG. 2H, a second photoresist pattern 176 is formed on the peripheral regions and selectively in the active pixel region over the interconnections and contacts, and skipping areas above the photo conversion elements 106. Then, by etching the interlayer dielectric structure 200 of the action pixel region, including contact 114, contact 128 and interconnection 130, second openings (cavities) 178 above the photo conversion elements 106 are formed. The bottom of the opening has a distance, which is separated by the first interlayer dielectric layer 104, from the photo conversion elements 106. The second photoresist pattern 176 is then removed.

As illustrated in FIG. 21, a transparent filling material 180 is deposited in the cavity openings 178. The transparent filling material 180 preferably has a higher refractive index than other interlayer dielectric layers to prevent the loss of light to the outside environment and to prevent penetration of light to an adjacent pixel. For example, if the fifth interlayer dielectric layer 134 is FSG, which has a refractive index of 1.4, then the filling material should have a refractive index of greater than 1.4. The filling material 180 may be a resin or a flowable oxide.

As illustrated in FIG. 2J, a first flattening layer 182 is formed on the transparent filling material 180 and the fourth etch stop layer 132. The first flattening layer 182 may have a thickness of from about 0.2 μm to about 0.6 μm.

Referring to FIG. 1B, a color filter 184, which may be formed of a photoresist material containing color, e.g., red, blue or green, is formed on the first flattening layer 182. A second flattening layer 186 is formed on the color filters 184. Then, a lens assembly 188 is formed on the second flattening layer 186. The lens assembly 188 is preferably shaped, such as convexly toward below, to enhance optical signals traversing incident to the lens assembly 188, and directed through the color filters and optical passages to the photo conversion elements 106. The optical signals are received by the photo conversion elements 106 and converted into electrical signals.

It can be seen from the above described process that the distance of travel of the optical signals from the lens assembly 188 and the photo conversion elements 106 is minimize, or in any case, shorter than the distance or thickness between the top of the image sensor device at PAD 164 to the substrate 100. This process produces an image sensor device that has higher photo sensitivity, higher density, e.g., a design rule at or below 0.13 μm, with reduced crosstalk.

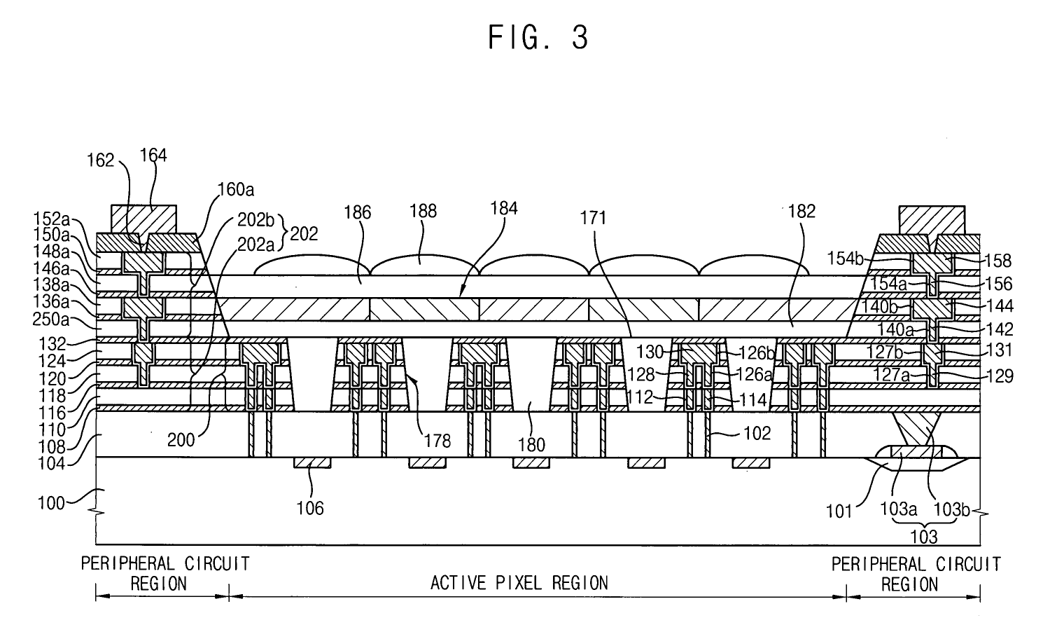

FIG. 3 illustrates another embodiment of the present invention. This embodiment including the processes is similar to that of the embodiment in FIG. 1B except for the thickness of the fifth interlayer dielectric layer 250a. In this embodiment, the fifth interlayer dielectric layer 250a is substantially the same thickness as that of the other interlayer dielectric layers 110, 118, 124, 138a, 148a and 152a.

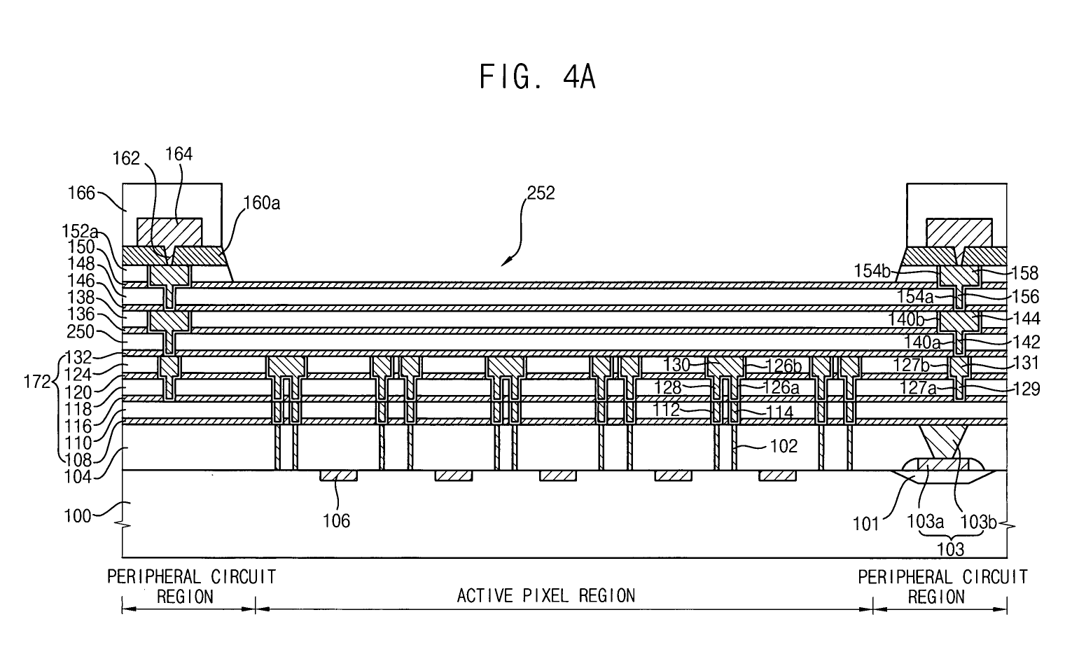

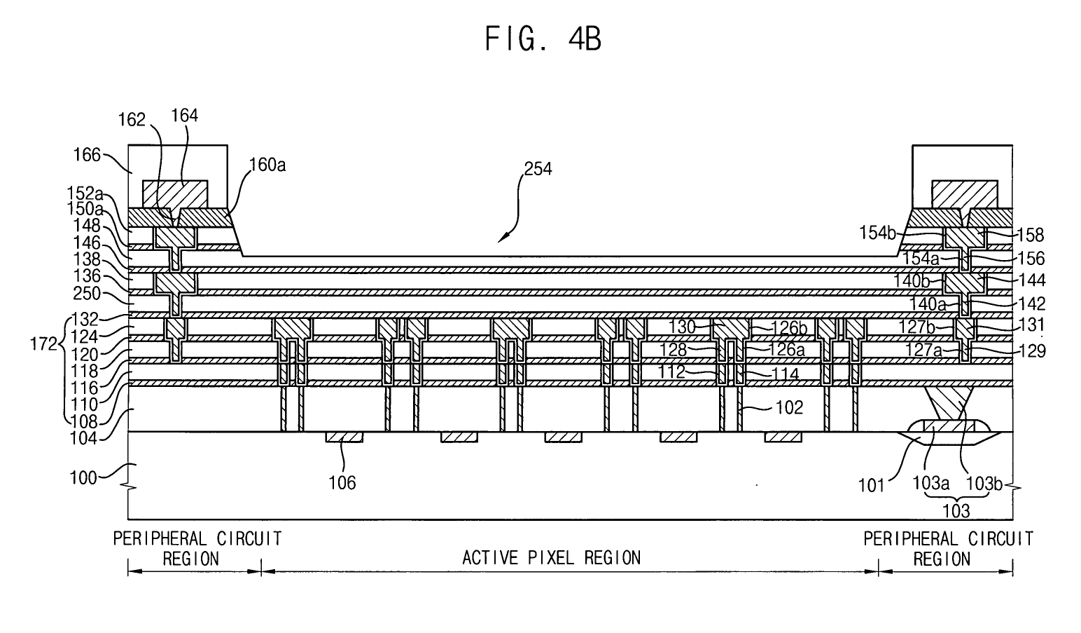

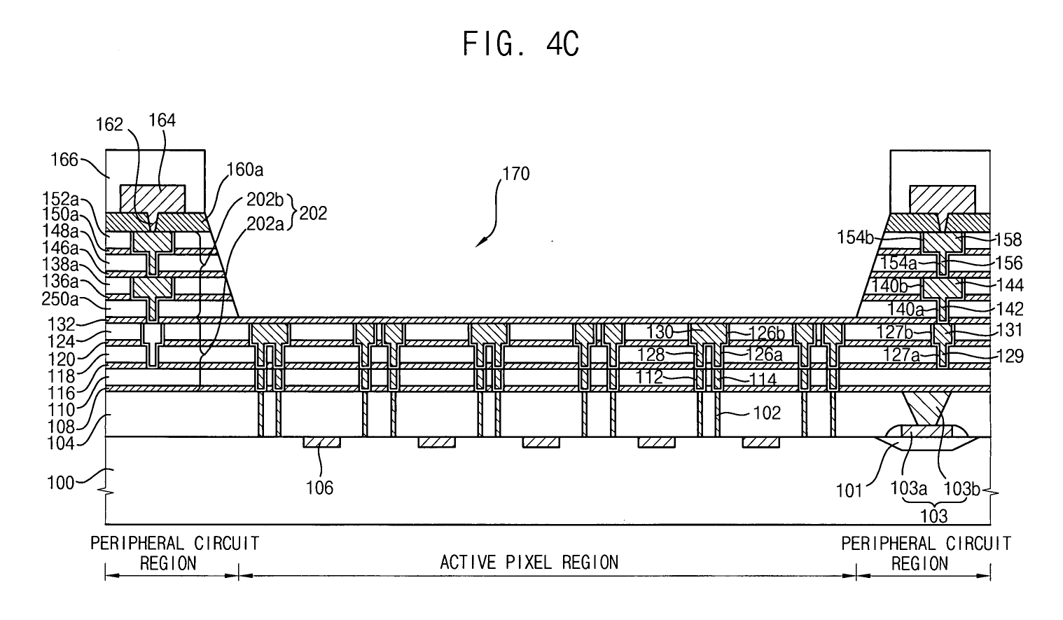

FIGS. 4A to 4B illustrate a method of forming the device according to FIG. 3. Other than the thickness of the fifth interlayer dielectric layer 250a, the processes of forming the interlayer dielectric structure, etch stop layers, to the forming of the PAD are the same as described above for the embodiment of FIG. 1B. As shown in FIG. 4A, a first preliminary recess region 252 is formed by etching the passivation layer 160, and the eighth interlayer dielectric layer 152a. FIG. 4B shows etching of the seventh etch stop layer 150a to form second preliminary recess region 254. FIG. 4C illustrates that the remaining fifth interlayer dielectric layer 250a is etched to form a recessed region 170, which provides an opening in the active pixel region to reveal the fourth etch stop layer 132. By reducing the thickness of the fifth interlayer dielectric layer 250a as compared to the embodiment of FIG. 1B, the overall thickness of the optical path from the lens assembly 188 to the photo conversion elements 106 is further reduced.

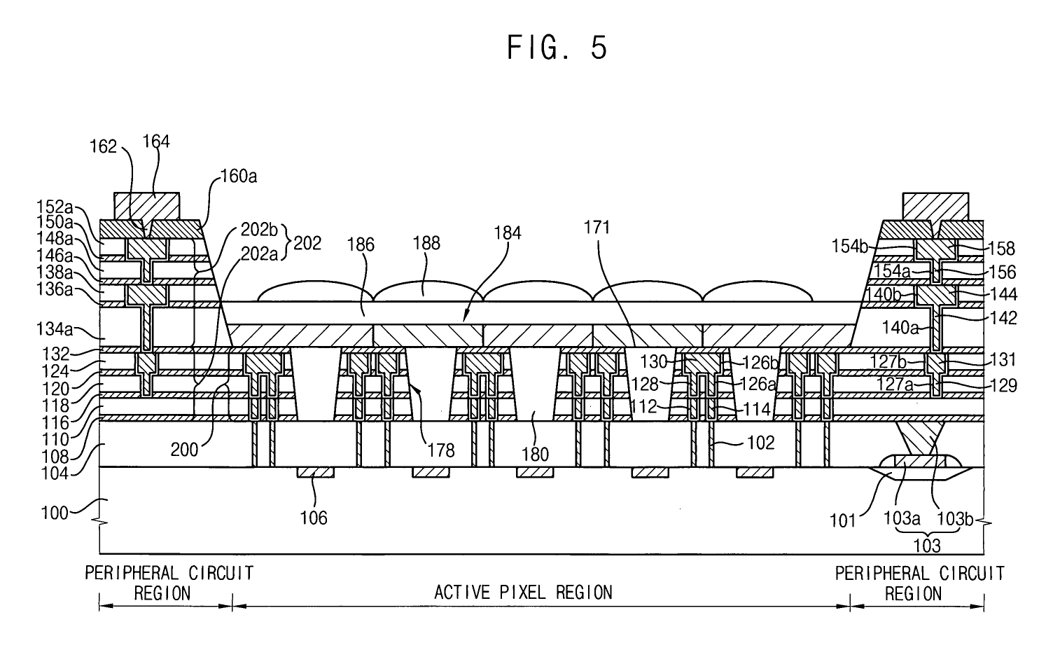

FIG. 5 illustrates another embodiment of the present invention. In particular, the location of the color filter 184 is changed relative to the embodiments of FIGS. 1B and 3. This embodiment does not include the formation of the first flattening layer 182.

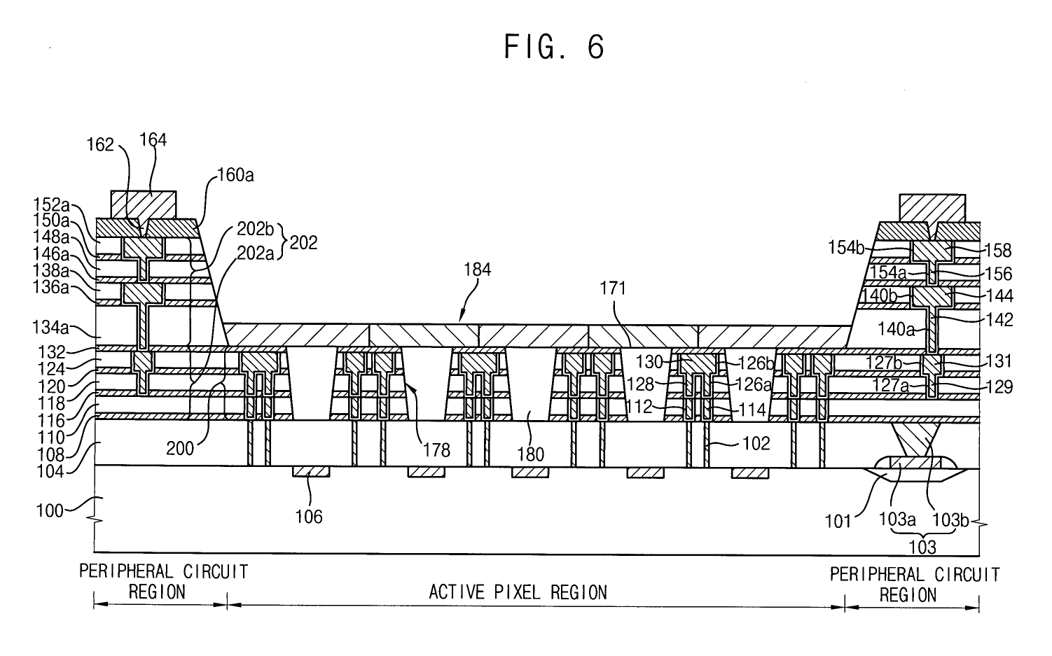

FIG. 6 illustrates a method for forming the device according to FIG. 5. In particular, the color filters 184 are formed directly on the transparent filling material 180 and the fourth etch stop layer 132.

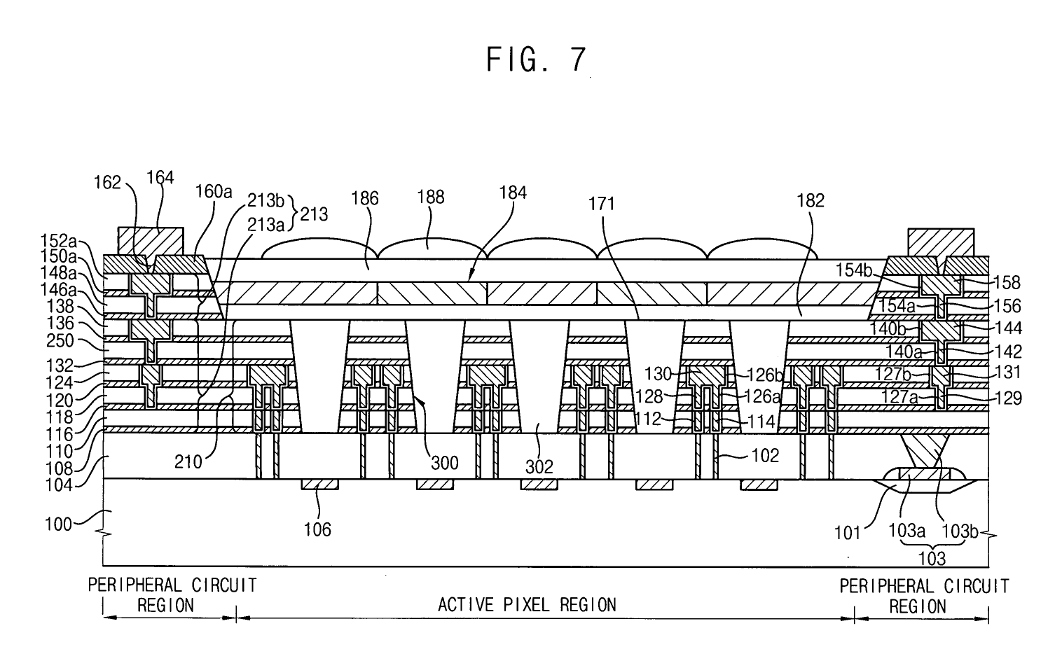

FIG. 7 illustrates yet another embodiment of the present invention. In this embodiment, the interlayer dielectric structures of the active pixel region are different from that of the embodiments of FIGS. 1B, 3 and 5. In particular, the interlayer dielectric structure 210 of the active pixel region includes the first, second, third, fourth and fifth etch stop layers (108, 116, 120, 132 and 136, respectively) and the second, third, fourth, fifth and sixth interlayer dielectric layers (110, 118, 124, 250 and 138, respectively).

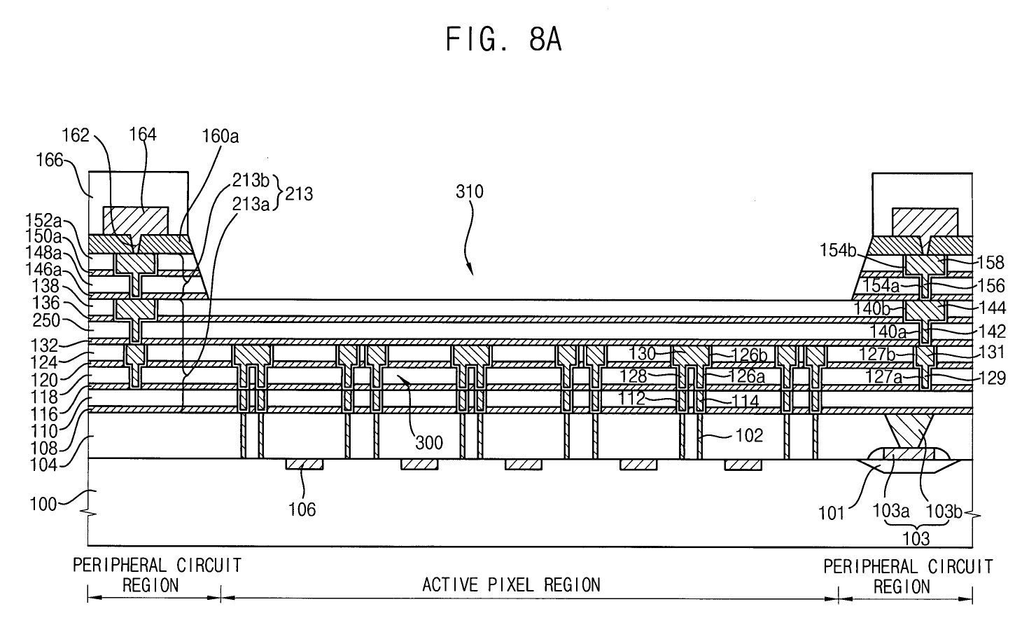

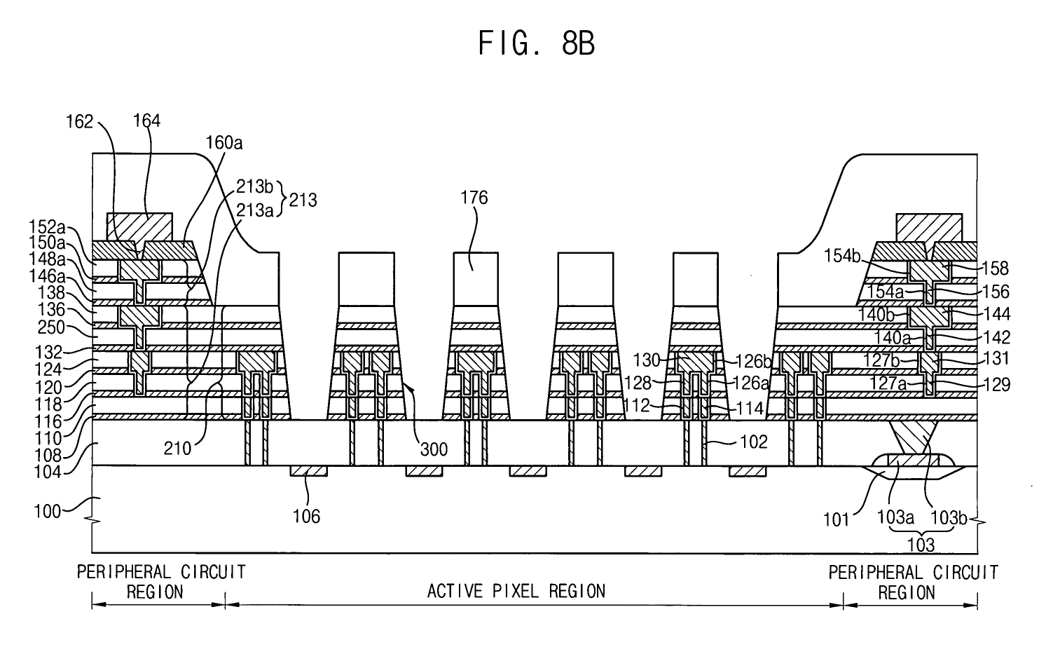

FIGS. 8A and 8B illustrate a method for forming the device according to FIG. 7. In particular, FIG. 8A illustrates a preliminary recess region 310 is formed by etching the passivation layer 160 and a part of the interlayer dielectric structure of the active pixel region. In FIG. 8B, a second photoresist pattern 176 is formed having openings above each of the respective photo conversion elements 106. A second opening (cavity opening) 302 is formed by etching the interlayer dielectric structure 210 of the active pixel region. This interlayer dielectric structure 200 includes the contact 114, the contact 128 and the interconnection 130. The bottom of the opening has a distance, which is separated by the first interlayer dielectric layer 104, from the photo conversion element. The second photoresist pattern 176 is then removed.

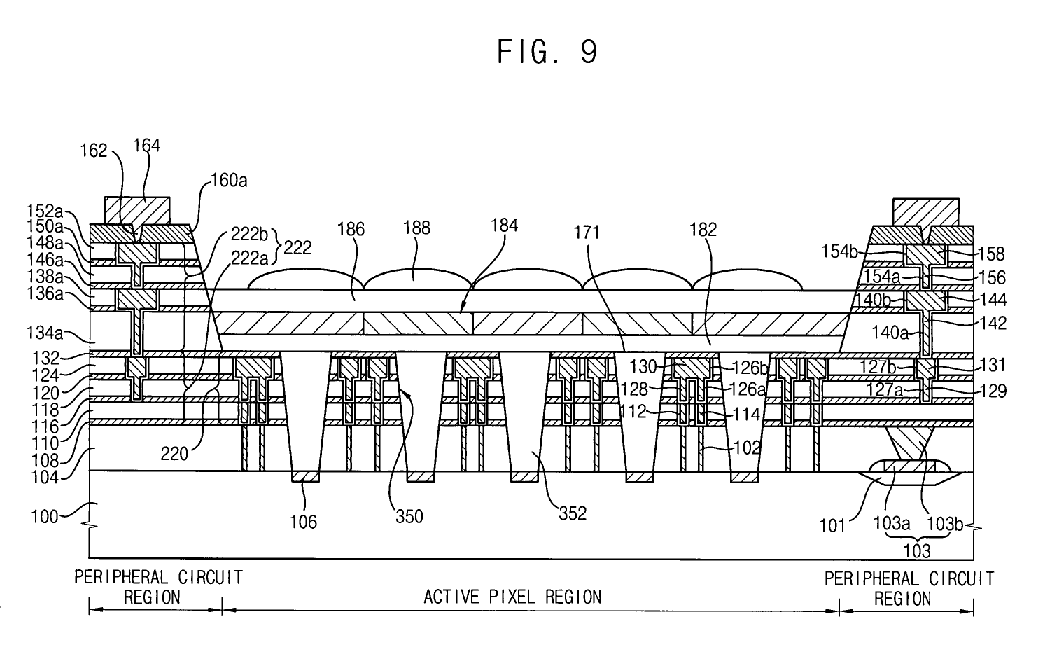

FIG. 9 illustrates another embodiment of the present invention. This embodiment is similar to that of the embodiments of FIGS. 1B, 3, 5 and 7 except that the distance of the bottom of the second openings (cavity opening) 352 to the photo conversion elements 106. In this embodiment, the bottom of the second openings 352 is in direct contact with the corresponding photo conversion element 106.

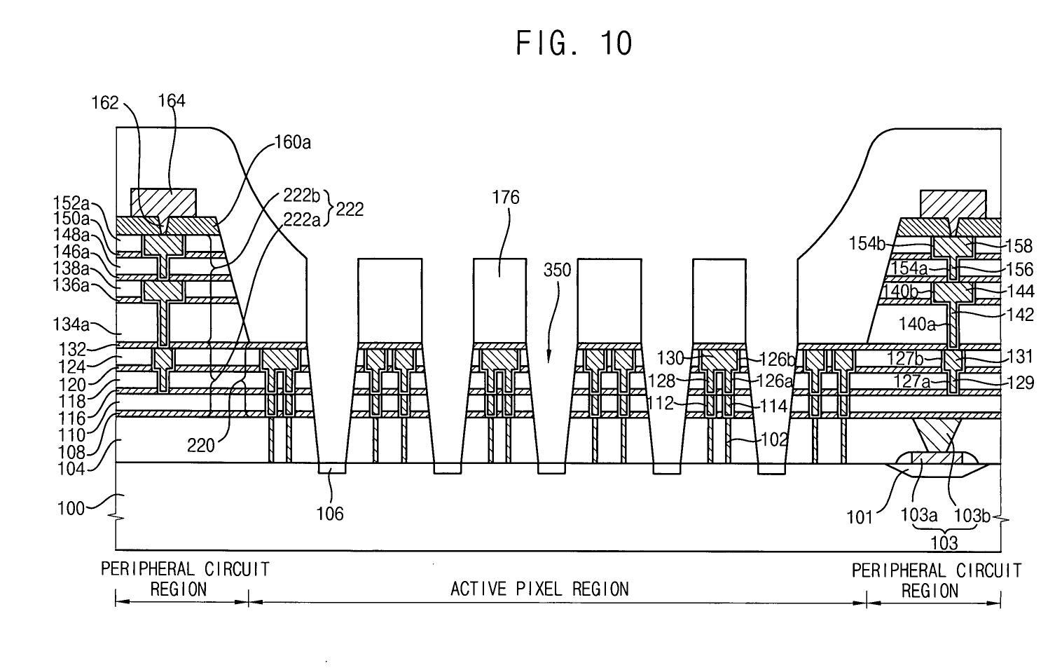

FIG. 10 illustrates a method for forming the device according to FIG. 9. In particular, FIG. 9 illustrates etching the interlayer dielectric structure of the active pixel region to reveal the photo conversion elements 106.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming an image sensor device, comprising:
providing a substrate having an active pixel region and a peripheral circuit region;
disposing a plurality of photo conversion elements in the active pixel region;
forming a plurality of transistors in the active pixel region and the peripheral circuit region (or above the substrate);
forming on top of the substrate a plurality of layers of interlayer dielectrics having an etch stop layer between each adjacent layer of interlayer dielectric;
forming interconnections within the interlayer dielectrics connecting to respective photo conversion elements;
providing a recess in the active pixel region by etching a plurality of layers of interlayer dielectrics;
providing openings through remaining plurality of layers of interlayer dielectrics to form an optical path for the photo conversion elements;
filling the openings with transparent material; and
forming color filters and lens above the openings,
wherein the distance of the optical path from the photodiode to the lens is shorter than the distance from the substrate to the top layer of interlayer dielectric in the peripheral circuit region.

2. The method of claim 1, wherein at least one of the layers of interlayer dielectrics is made of transparent material.

3. The method of claim 1, wherein the transparent material has a higher refractive index than that of the interlayer dielectrics.

4. The method of claim 1, wherein the transparent material is made from one of resin and flowable oxide.

5. The method of claim 1, wherein the interconnections are made of copper.

6. The method of claim 5, wherein the Interconnections are surrounded by a barrier layer.

7. The method of claim 1, wherein the transparent material contacts the photo conversion elements.

8. The method of claim 1, wherein there are at least four layers of interlayer dielectrics between the lens and the photo conversion elements and at least three additional layers of interlayer dielectrics to the top of the image sensor device.

9. The method of claim 1, wherein a sloping wall is formed in the recess in the active pixel region from etching of the layers of interlayer dielectrics.

10. A method of forming an image sensor device, comprising:
forming an active pixel region with a plurality of photo conversion elements disposed in a substrate;
forming a plurality of transistors electrically connecting to respective photo conversion elements in the active pixel region;
forming a first interlayer dielectric on the substrate;
forming first metal contacts through the first interlayer dielectric;
forming a first etch stop layer on the first interlayer dielectric;
forming a second interlayer dielectric on the etch stop layer;
forming first interconnections through the second interlayer dielectric and connecting to the metal contacts;
forming a second etch stop layer on the second interlayer dielectric;
forming a third interlayer dielectric, a third etch stop, and a fourth interlayer dielectric on the second etch stop layer;
forming second interconnections through the third interlayer dielectric, forming a fourth etch stop layer;
depositing a fifth interlayer dielectric, a fifth etch stop and a sixth interlayer dielectric sequentially on the fourth etch stop layer;
forming third and fourth interconnections;
forming a recess region in the active pixel region by etching the layers of interlayer dielectrics and etch stop layers to reveal the fourth etch stop layer;
forming openings corresponding to the photo conversion elements by selectively etching the layers of interlayer dielectrics and etch stop layers above the photo conversion elements;
depositing a transparent filling material in the opennings;
forming color filters;
forming a flattening layer on the color filters; and
forming a plurality of lenses on the flattening layer.

11. The method of claim 10, wherein the fifth interlayer dielectric is about 1.5 to about 3 times thicker than its adjacent interlayer dielectrics.

12. The method of claim 10, wherein the first interlayer dielectrics is made of transparent material.

13. The method of claim 10, wherein the filling material has a higher refractive index than the interlayer dielectrics.

14. The method of claim 10, wherein the filling material is made from one of resin and flowable oxide.

15. The method of claim 10, wherein the first flattening layer is about 0.2 um to about 0.6 um in thickness.

16. The method of claim 10, wherein the layers of interlayer dielectrics have substantially the same thickness except the first interlayer dielectric.

17. The method of claim 10, further including forming a flattening layer between the filling material and the color filters.

18. The method of claim 10, wherein the interconnections are made of copper.

19. The method of claim 18, wherein the interconnections are surrounded by barrier metal layers.

20. The method of claim 10, wherein the filling material contacts the photo conversion elements.

21. The method of claim 10, wherein the substrate is made of silicon or SOI.

22. The method of claim 10, wherein the step of forming the recess region includes forming a sloping wall.

23. An image sensor device, comprising:
a substrate having an active pixel region and a peripheral circuit region;
a plurality of photo conversion elements disposed in the active pixel region, each photodiode is configured to receive light through a lens and an opening formed between a plurality of layers of interlayer dielectrics formed on top of each other above the substrate; and
a plurality of interconnections electrically connecting to the photo conversion elements disposed within the active pixel region, wherein the distance between the lens and the photo conversion elements is shorter than the distance between the substrate and the top layer of interlayer dielectric in the peripheral circuit region.

24. The device of claim 23, wherein the interconnections are made of copper.

25. The device of claim 24, wherein each of the interconnections is surrounded by a barrier metal layer.

26. The device of claim 23, further including color filters disposed between the lens and the photo conversion elements.

27. The device of claim 23, wherein there are at least four layers of interlayer dielectrics between the lens and the photo conversion elements and at least three additional layers of interlayer dielectrics to the top of the image sensor device.

28. The device of claim 23, wherein the openings are filled with optically transparent material.

29. The device of claim 28, wherein the optically transparent material in the openings directly contact the photo conversion elements.

30. The device of claim 23, wherein at least one of the layers of interlayer dielectrics is thicker than the other layers of interlayer dielectrics.

31. An image sensor device, comprising:
an active pixel region with a plurality of photo conversion elements disposed in a substrate;
a first interlayer dielectric formed on the substrate;
first metal contacts formed through the first interlayer dielectric;
a first etch stop layer formed on the first interlayer dielectric;
a second interlayer dielectric formed on the first etch stop layer;
first interconnections formed through the second interlayer dielectric and electrically connected to the metal contacts;
a second etch stop layer formed on the second interlayer dielectric;
a third interlayer dielectric, a third etch stop, and a fourth interlayer dielectric formed above the second etch stop layer;
second interconnections formed through the third interlayer dielectric;
a fourth etch stop layer formed on the fourth interlayer dielectric;
a peripheral circuit region disposed adjacent the active pixel region, the peripheral circuit region comprising at least two additional interlayer dielectrics interposed between two etch stop layers;
a plurality of openings above the photo conversion elements, the openings are filled with optically transparent material;
a plurality of color filters disposed above the openings;
a flattening layer formed on the color filters; and
a plurality of lenses formed on the flattening layer.

32. The device of claim 31, wherein the interconnections are made of copper.

33. The device of claim 32, wherein each of the interconnections is surrounded by a barrier metal layer.

34. The device of claim 31, wherein the optically transparent material in the openings directly contact the photo conversion elements.

35. The device of claim 31, wherein at least one of the layers of interlayer dielectrics is thicker than the other layers of interlayer dielectrics.

36. The device of claim 31, further including a flattening layer formed between the filling material and the color filters.

37. The device of claim 31, wherein at least one of the layers of interlayer dielectrics is made of transparent material.

38. The device of claim 31, wherein the optically transparent material has a higher refractive index than that of the interlayer dielectrics.

39. The device of claim 31, wherein the first additional interlayer dielectric in the peripheral circuit region has a larger thickness than its adjacent interlayer dielectrics.
